(19) United States
(12) Patent Application Publication
(10) Pub. No.: US 2014/0346451 A1
(43) Pub. Date: Nov. 27, 2014

(54) ADHESIVE FILM AND ORGANIC LIGHT EMITTING DISPLAY USING THE SAME

(71) Applicant: SAMSUNG DISPLAY CO., LTD, YONGIN-CITY (KR)

(72) Inventor: Hyun-Joon OH, Yongin-City (KR)

(73) Assignee: SAMSUNG DISPLAY CO., LTD, YONGIN-CITY (KR)

(21) Appl. No.: 14/031,916

(22) Filed: Sep. 19, 2013

(30) Foreign Application Priority Data
May 24, 2013 (KR) 10-2013-0058906

(51) Int. Cl. C09J 7/02; H01L 51/52

(52) U.S. Cl. CPC C09J 7/025; H01L 51/5253; H01L 51/5259; C09J 2203/326; C09J 2201/28
USPC 257/40; 428/166; 428/116; 428/41.4; 428/40.5; 428/40.7

(57) ABSTRACT

There is provided an adhesive film and an organic light emitting display using the same. The adhesive film includes a first protective layer, an adhesive layer and a second protective layer. The adhesive layer is formed on the first protective layer and has a pattern formed in one surface thereof, the pattern including one or more openings shaped and sized to accommodate particulate matter. The second protective layer is formed on the adhesive layer.

### RELATED APPLICATIONS

This application claims priority to, and the benefit of, Korean Patent Application No. 10-2013-0058906, filed on May 24, 2013 in the Korean Intellectual Property Office, the contents of which are incorporated herein by reference in their entirety.

### BACKGROUND

1. Field

An aspect of the present disclosure relates generally to flat panel displays. More specifically, an aspect of the present disclosure relates to an adhesive film and an organic light emitting display using the same.

2. Description of the Related Art

An organic light emitting display produces images using organic light emitting diodes that generate light through recombination of electrons and holes. The organic light emitting display is known for its fast response speed and low power consumption. Hence, the organic light emitting display has received attention as a potential next-generation display.

The organic light emitting display includes a substrate, an organic light emitting portion positioned on the substrate and including an organic light emitting diode, and a sealing member that, together with the substrate, seals the organic light emitting portion.

The organic light emitting diode is very susceptible to damage from moisture and oxygen, and is also vulnerable to mechanical damage due to the tendency to make their overlying display panels as large and thin as possible. Accordingly, an adhesive layer that performs the function of a filling material covers a front side of the organic light emitting portion, thereby protecting the organic light emitting diode.

### SUMMARY

Embodiments provide an adhesive film and an organic light emitting display using the same, where the adhesive film is configured in such a manner as to help prevent failures in the organic light emitting display that are caused by particles.

According to an aspect of the present invention, there is provided an adhesive film, including: a first protective layer; an adhesive layer formed on the first protective layer and having a pattern formed in one surface thereof, the pattern including one or more openings shaped and sized to accommodate particulate matter; and a second protective layer formed on the adhesive layer.

The pattern of the adhesive layer may be formed through a roll-to-roll process.

The depth of the pattern may be equal to or less than about ½ of the thickness of the adhesive film, and the width of the pattern may be about 0.5 μm or more.

The pattern may have a honeycomb structure.

The adhesive layer may include a first adhesive layer coated on a front side of the first protective layer, and a second adhesive layer having the pattern printed therein.

The adhesive layer may be formed of one or more materials selected from the group consisting of epoxy resin, acryl resin, silicon, ethylene vinyl acetate (EVA) and polyethylene (PE).

The adhesive layer may be formed on the first protective layer, by at least one of micro gravure coating, comma coating, slot die coating, screen printing, spin casting and printing.

The thickness of the adhesive layer may be from about 5 to about 100 μm.

The first and second protective layers may each be formed of one or more materials selected from the group consisting of polyethylene terephthalate (PET), polyimide (PI), polyethylene series (PE, LLDPE, LDPE or HDPE), polycarbonate (PC) and polyamide (PA).

At least one of the first and second protective layers may be a release film formed by release-treating a contact surface of the release film with a material including at least one of wax, silicon and fluorine.

The first protective layer may have a processing pattern formed therein, so that the pattern of the adhesive layer is formed when material of the adhesive layer is applied to the first protective layer so as to conform to the processing pattern.

The thickness of the first protective layer may be from about 20 to about 300 μm.

The thickness of the second protective layer may be about 50 μm or less.

According to an aspect of the present invention, there is provided an organic light emitting display, including: a first substrate; an organic light emitting portion including a first electrode positioned on the first substrate, an organic light emitting layer formed on the first electrode, and a second electrode formed on the organic light emitting layer; an adhesive layer positioned on the organic light emitting portion and having a pattern formed in a surface of the adhesive layer that contacts the organic light emitting portion, the pattern including one or more openings shaped and sized to accommodate particulate matter; and a second substrate positioned on the adhesive layer.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art. All stated numerical values are approximate, and may vary.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a sectional view of an adhesive film according to an embodiment of the present invention.

FIGS. 2A to 2E are views illustrating modified embodiments of uneven patterns of FIG 1.

FIGS. 3A and 3B are views illustrating a manufacturing method of the adhesive film.

FIGS. 4A and 4B are sectional views of adhesive films according to other embodiments of the present invention.

FIG. 5 is a schematic sectional view of an organic light emitting display using the adhesive film of FIG. 1 according to an embodiment of the present invention.

### DETAILED DESCRIPTION

Hereinafter, certain exemplary embodiments according to the present invention will be described in detail with reference to the accompanying drawings.

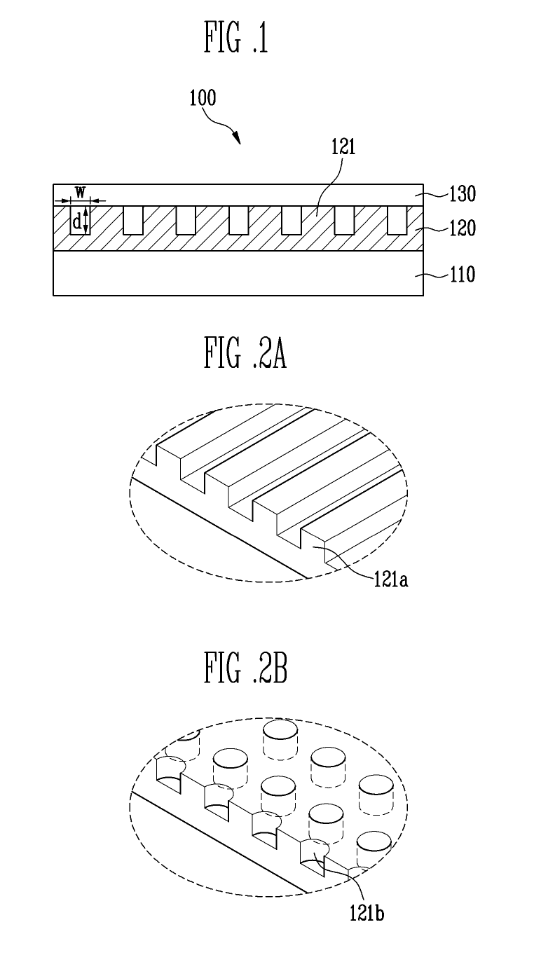

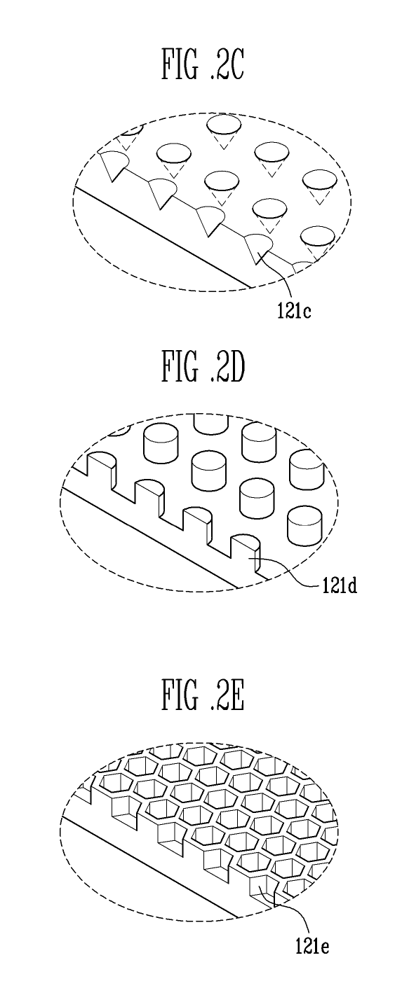

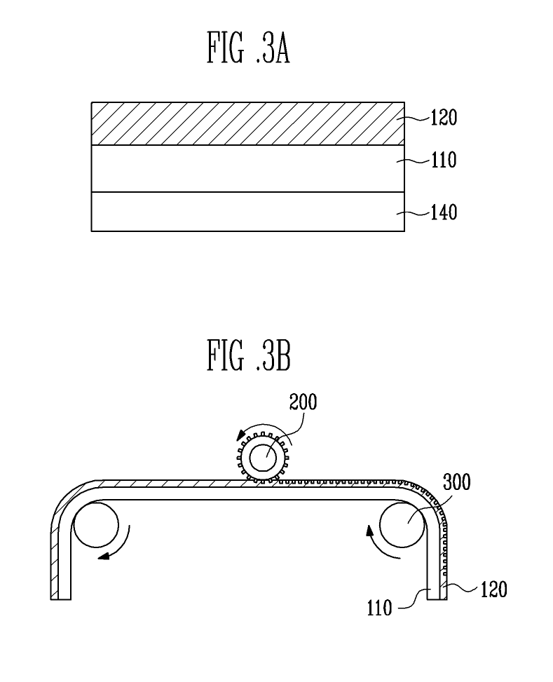

FIG. 1 is a sectional view of an adhesive film according to an embodiment of the present invention. FIGS. 2A to 2E are views illustrating modified embodiments of uneven patterns of FIG. 1.

Referring to FIG. 1, the adhesive film 100 according to this embodiment relates to an adhesive film or adhesive sheet for sealing in an organic light emitting display. The adhesive film 100 may include a first protective layer 110, an adhesive layer 120 formed on the first protective layer 110 and having an uneven pattern 121 formed in one surface thereof, and a second protective layer 130 formed on the adhesive layer 120.

The first protective layer (or base material film) 110 and the second protective layer (or cover film) 130 may be formed of materials respectively coated on one and the opposing surfaces of the adhesive layer 120.

The specific kind of the first protective layer 110 is not particularly limited. For example, the first protective layer 110 may be formed of one or more materials selected from the group consisting of polyethylene terephthalate (PET), polyimide (PI), polyethylene series (PE, LLDPE, LDPE or HDPE), polycarbonate (PC) and polyamide (PA). The first protective layer 110 may also be formed of any other suitable material.

The kind of the second protective layer 130 is also not particularly limited. For example, a kind of material identical to or different from that of the first protective layer 110 may be used for the second protective layer 130.

In an embodiment, each of the first and second protective layers 110 and 130 may be a release film formed by release-treating a contact surface with the adhesive layer 120, using a material including at least one of wax, silicon and fluorine.

Specifically, an appropriate release treatment may be performed on one or both inner surfaces of each of the first and second protective layer 110 and 130 (i.e. the surfaces facing the adhesive layer 120). An alkyd release agent, silicon release agent, fluorine release agent, unsaturated ester release agent, polyolefin release agent, wax release agent or the like may be used as an example of the release agent used in the release treatment. Among these release agents, the alkyd release agent, silicon release agent or fluorine release agent is often preferable for its thermal resistance properties, but the present invention is not limited thereto, and any release agent is contemplated.

The thickness of each of the first and second protective layers 110 and 130 is not limited to any particular value or values, and may be appropriately selected as necessary. However, the thickness of the first protective layer 110 is preferably about 20 to 300 μm. If the thickness of the first protective layer 110 is less than 20 μm, deformation or cracking of the first protective layer 110 may easily occur. If the thickness of the first protective layer 110 exceeds 300 μm, the first protective layer 110 is unnecessarily thick, and therefore, the economic efficiency of the first protective layer 110 may be lowered.

The thickness of the second protective layer 130 is also not limited to any particular value or values, and may be set within the same parameters as that of the first protective layer 110. Alternatively, the thickness of the second protective layer 130 may be set relatively thinner than that of the first protective layer 110, in consideration of process efficiency. For example, the thickness of the second protective layer 130 is preferably about 50 μm or less.

The adhesive layer 120 is used to protect the organic light emitting diode by covering a front side of the organic light emitting diode. The adhesive layer 120 is formed on the first protective layer 110 and has an uneven pattern 121 formed in one surface thereof.

The adhesive layer 120 may be formed of one or more materials selected from the group consisting of epoxy resin, acryl resin, silicon, ethylene vinyl acetate (EVA) and polyethylene (PE), but the present invention is not limited thereto. Any suitable material may be used.

The thickness of the adhesive layer 120 is preferably about 5 to 100 μm. If the thickness of the adhesive layer 120 is less than about 5 μm, deformation or cracking of the adhesive layer 120 may easily occur. If the thickness of the adhesive layer 120 exceeds about 100 μm, the adhesive layer 120 is unnecessarily thick, and therefore, the economic efficiency of the adhesive layer 120 may be lowered. However, the thickness of the adhesive layer 120 is not limited to these values, and may be appropriately selected in consideration of the use of the adhesive film to be applied.

Additionally, the adhesive layer 120 may be mixed with various additives when necessary. For example, in order to protect the organic light emitting diode, the adhesive layer 120 may include calcium oxide (CaO), barium oxide (BaO), magnesium oxide (MgO), magnesium (Mg) and calcium (Ca), which have, for example, high absorptivity of moisture and oxygen.

The adhesive layer 120 may be formed on the first protective layer 110, using at least one of micro gravure coating, comma coating, slot die coating, screen printing, spin casting, and printing, but the present invention is not limited thereto, and any process may be employed.

Meanwhile, in order to accommodate a particle in the uneven pattern 121, the depth d of the uneven pattern 121 is preferably approximately ½ or less of the thickness of the adhesive film 100, and the width w of the uneven pattern 121 is preferably about 0.5 μm or more.

Referring to FIGS. 2A to 2E, the uneven pattern 121 may have a structure such as a line pattern 121a (i.e. a series of linear ridges), lattice pattern, circular pattern 121b or polygonal pattern 121c, or may have a three-dimensional structure such as a column pattern or cone pattern 121c (where any polygonal pattern may be employed, such as conical patterns as shown, or any other shaped structures or patterns). Alternatively, the uneven pattern 121 may have an embossed pattern 121d or engraved pattern (of any shape) in addition to a combination of the patterns described above. The uneven pattern 121 preferably has the structure of honeycombs 121e, in consideration of mechanical strength, adhesion, maximization of the area of a cavity, etc. However, the present invention is not limited thereto, and any shaped structure or structures may be employed.

One of ordinary skill in the art will acknowledge that the uneven pattern 121 may employ structures of any shape and distribution. Also, the number of the uneven patterns 121 per unit area and the interval between the patterns are not limited by the embodiments shown, and may be appropriately set in any manner as desired.

FIGS. 3A and 3B are views illustrating a manufacturing method of the adhesive film.

Referring to FIGS. 3A and 3B, the uneven patterns 121 of the adhesive layer 120 may be formed through a roll-to-roll process using a forming roller 200 after the adhesive layer 120 is formed on the first protective layer 110.

In an embodiment, a process may be performed by attaching a carrier film 140 with weak viscosity to the outside of the first protective layer 110, which is then removed after the manufacturing of the adhesive film 100 is completed.

The first protective layer 110 having the adhesive layer 120 formed thereon is horizontally moved using a transfer roller 300 such as that used in a known conveyor system. The forming roller 200 is rotatably mounted on the transfer roller 300. In this case, forming patterns corresponding to the respective uneven patterns 121 are formed in the forming roller 200. As the first protective layer 110 having the adhesive layer 120 formed thereon passes through the forming roller 200, and the forming patterns are pressed into the adhesive layer 120, forming the uneven patterns 121 on the upper surface of the adhesive layer 120.

After the uneven patterns 121 are formed in the adhesive layer 120, the second protective layer 130 is coated on the adhesive layer 120, thereby completing the adhesive film 100.

Additionally, in the adhesive film 100, the adhesive layer 120 may be cured through a predetermined curing process. The cured adhesive layer 120 has a form with a dense texture, and thus is advantageous in terms of device reliability. On the other hand, dark spots may sometimes be formed in the adhesive layer 120 during the curing process, which can be undesirable. Accordingly, while the curing process may be included in the fabrication of film 100, it may also be excluded as desired.

The aforementioned manufacturing method of the adhesive film 100 is not limited to the process or processes described above, and various methods known in the art may be used when necessary.

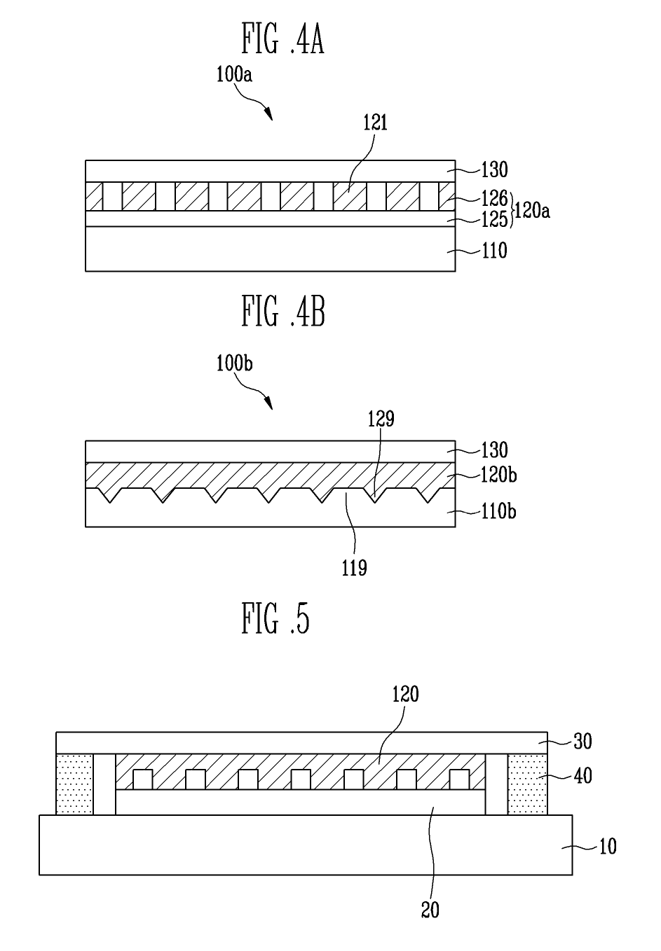

FIGS. 4A and 4B are sectional views of adhesive films according to other embodiments of the present invention. In FIGS. 4A and 4B, components identical to those of the aforementioned embodiment are designated by like reference numerals, and their detailed descriptions will be omitted to avoid redundancy.

Referring to FIG. 4A, an adhesive layer 120a of the adhesive film 100a according to this embodiment includes a first adhesive layer 125 coated on a front side of the first protective layer 110, and a second adhesive layer 126 in which the uneven patterns 121 are printed.

The adhesive film 100a has a multi-layered structure in which the first adhesive layer 125 is primarily coated on the first protective layer 110, and the second adhesive layer 126 having the uneven patterns 121 printed therein is secondarily coated on the first adhesive layer 125, using a printing method such as inkjet printing.

The first and second adhesive layers 125 and 126 may be formed of the same material, or may be formed of different materials within the scope of the materials mentioned in the aforementioned embodiment. The thicknesses of each of the first and second adhesive layers 125 and 126 are not limited to any particular values, and may be freely set within the range where the thickness of the overall adhesive layer 120a is about 5 to about 100 μm, or whatever overall thickness is desired for any particular application.

Referring to FIG. 4B, in the adhesive film 100b according to this embodiment, a separate patterning process of forming uneven patterns is not performed on an adhesive layer 120b, but countermeasure patterns 129 are formed in the adhesive layer 120b, respectively corresponding to processing patterns 119 formed in a first protective layer 110b.

That is, after the patterning process of forming the processing patterns 119 is performed on the first protective layer 110b rather than the adhesive layer 120b, the countermeasure patterns 129 are formed in one surface of the adhesive layer 120b by roll-coating or press-compressing the uncured adhesive layer 120b onto the first protective layer 110b.

Meanwhile, although it has been described in the aforementioned embodiments that the adhesive film has a triple-layered structure in which the first protective layer, the adhesive layer and the second protective layer are sequentially laminated, the adhesive film may have a triple- or more-layered structure further including one or more additional adhesive layers or protective layers, and/or any combination thereof.

FIG. 5 is a schematic sectional view of an organic light emitting display using the adhesive film of FIG. 1 according to an embodiment of the present invention.

Referring to FIG. 5, the organic light emitting display according to this embodiment may include a first substrate 10, an organic light emitting portion 20, an adhesive layer 120, a second substrate 30 and a sealing member 40.

The first substrate 10 may be formed of a transparent insulative material including polymer, metal, glass, quartz, etc. In a case where the first substrate 10 is formed of a transparent material, an image displayed in the organic light emitting portion 20 is viewed from the outside of the organic light emitting display through the first substrate 10.

Although not described in detail, the organic light emitting portion 20 includes a first electrode positioned on the first substrate 10, an organic light emitting layer formed on the first electrode, and a second electrode formed on the organic light emitting layer.

Here, the electrode may be a hole injection electrode (anode electrode), and the second electrode may be an electron injection electrode (cathode electrode). The organic light emitting layer may include a hole injection layer (HIL), a hole transport layer (HTL), an emissive layer (EML), an electron transport layer (ETL) and an electron injection layer (EIL), which are sequentially laminated from the first electrode 21.

If power is supplied from an external power supply portion (not shown) to the first and second electrodes, holes and electrons are injected into the organic light emitting layer EL from the respective first and second electrodes, and excitons each generated by coupling the hole and the electron are changed from an excited state to a ground state, thereby emitting light.

The organic light emitting portion 20 may further include a driving transistor, an insulating layer or a passivation layer.

The second substrate 30 is a sealing substrate coupled to the first substrate 10 which has the organic light emitting portion 20 formed thereon. The second substrate 30 may be formed of a material having flexibility, transparency and high thermal resistance and chemical resistance characteristics.

In an embodiment, the second substrate 30 may be formed of a metal sheet or metal film having flexibility.

The adhesive layer 120 is positioned on the organic light emitting portion 20, and may be attached to the second substrate 30 so that the surface having the uneven patterns 121 formed therein comes in contact with the organic light emitting portion 20. The adhesive layer 120 may be attached to the second substrate 30 by being cut to have a shape capable of covering the organic light emitting portion 20.

More specifically, the adhesive film 100 is attached to the second substrate 30 while the first protective layer 110 of the adhesive film 100 is removed. The second protective layer 130 may be removed in the process of joining together the first and second substrates 10 and 30. In this case, the uneven patterns 121 of the adhesive layer 120 are necessarily positioned on a surface of the second substrate 30, which faces the organic light emitting portion 20.

Methods known in the art may be used as the method of removing the first and second protective layers 110 and 130 from the adhesive film 100, and the present invention is not limited thereto.

Meanwhile, the sealing member 40 is interposed between the first and second substrates 10 and 20 so as to hermetically seal the organic light emitting display. The sealing member 40 is positioned to surround the organic light emitting portion 20.

Additionally, a moisture absorption filling material (not shown) may be positioned between the organic light emitting portion 20 and the second substrate 30 at the inside of the sealing member 40.

The organic light emitting display is manufactured through an encapsulation process in which the first substrate 10 having the organic light emitting portion 20 formed thereon and the second substrate 30 having the adhesive layer 120 formed thereon are joined together to face each other.

By way of summation and review, an adhesive film for a filling material in an organic light emitting display includes an adhesive layer and protective films respectively attached to upper and lower surfaces of the adhesive layer so as to prevent the adherence of foreign matter to the adhesive layer, where this foreign material can cause damage to the adhesive layer. The adhesive layer and the protective film coated on the adhesive layer can be formed to have substantially flat surfaces. In this case, the protective film is removed when the adhesive layer is adhered to a front side of an organic light emitting portion.

However, in a case where the adhesive layer has a flat structure with none of the grooves or empty spaces of, for example, FIG. 1, it is possible to maximize the adhesion of the adhesive layer, as more material exists to adhere to the organic light emitting portion. However, when foreign matter such as particles are interposed between the adhesive layer and an organic light emitting diode in the organic light emitting portion, a physical force generated by impact applied from the outside of a panel or deformation of the panel (particularly, a flexible panel) may be transferred to the organic light emitting diode via the particles.

Since the organic light emitting diode is vulnerable to damage from applied physical force, the existence of particles causes the organic light emitting diode to be more easily damaged, thus causing defects such as dark spots.

Therefore, according to the organic light emitting display of the present invention, uneven patterns for accommodating particles are formed on one surface of the adhesive layer, so that it is possible to minimize damage to the organic light emitting diode caused by contact with the particles. Further, it is possible to reduce the occurrence of dark spots in the organic light emitting display due to damage of the organic light emitting diode.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An adhesive film, comprising:
a first protective layer;
an adhesive layer formed on the first protective layer and having a pattern formed in one surface thereof, the pattern including one or more openings shaped and sized to accommodate particulate matter; and
a second protective layer formed on the adhesive layer.

2. The adhesive film of claim 1, wherein the pattern of the adhesive layer is formed through a roll-to-roll process.

3. The adhesive film of claim 1, wherein a depth of the pattern is equal to or less than about ½ of a thickness of the adhesive film, and a width of the pattern is about 0.5 μm or more.

4. The adhesive film of claim 1, wherein the pattern has a honeycomb structure.

5. The adhesive film of claim 1, wherein the adhesive layer includes a first adhesive layer coated on a front side of the first protective layer, and a second adhesive layer having the pattern printed therein.

6. The adhesive film of claim 1, wherein the adhesive layer is formed of one or more materials selected from the group consisting of epoxy resin, acryl resin, silicon, ethylene vinyl acetate (EVA) and polyethylene (PE).

7. The adhesive film of claim 1, wherein the adhesive layer is formed on the first protective layer by at least one of micro gravure coating, comma coating, slot die coating, screen printing, spin casting, and printing.

8. The adhesive film of claim 1, wherein a thickness of the adhesive layer is from about 5 to about 100 μm.

9. The adhesive film of claim 1, wherein the first and second protective layers are each formed of one or more materials selected from the group consisting of polyethylene terephthalate (PET), polyimide (PI), polyethylene series (PE, LLDPE, LDPE or HDPE), polycarbonate (PC) and polyamide (PA).

10. The adhesive film of claim 1, wherein at least one of the first and second protective layers is a release film formed by release-treating a contact surface of the release film with a material including at least one of wax, silicon and fluorine.

11. The adhesive film of claim 1, wherein the first protective layer has a processing pattern formed therein, so that the pattern of the adhesive layer is formed when material of the adhesive layer is applied to the first protective layer so as to conform to the processing pattern.

12. The adhesive film of claim 1, wherein a thickness of the first protective layer is from about 20 to about 300 μm.

13. The adhesive film of claim 1, wherein a thickness of the second protective layer is about 50 μm or less.

14. An organic light emitting display, comprising:
a first substrate;
an organic light emitting portion including a first electrode positioned on the first substrate, an organic light emitting layer formed on the first electrode, and a second electrode formed on the organic light emitting layer;
an adhesive layer positioned on the organic light emitting portion and having a pattern formed in a surface of the adhesive layer that contacts the organic light emitting portion, the pattern including one or more openings shaped and sized to accommodate particulate matter; and
a second substrate positioned on the adhesive layer.
